(19) United States
(12) Patent Application Publication
(10) Pub. No.: US 2017/0033804 A1
(43) Pub. Date: Feb. 2, 2017

(54) Method and Apparatus for Processing Information

(71) Applicant: ZTE Corporation, Shenzhen (CN)

(72) Inventors: Liguang LI, Shenzhen (CN); Jun XU, Shenzhen (CN); Zhifeng YUAN, Shenzhen (CN); Jin XU, Shenzhen (CN); Kaibo TIAN, Shenzhen (CN)

(21) Appl. No.: 15/118,287

(22) PCT Filed: Sep. 4, 2014
(86) PCT No.: PCT/CN2014/085949

§ 371 Date: Oct. 12, 2016

(30) Foreign Application Priority Data
Feb. 12, 2014 (CN) 201410049187.4

(51) Int. Cl. H03M 13/11; H03M 13/00; H04L 1/00; G06F 17/16

(52) U.S. Cl. CPC H03M 13/118; G06F 17/16; H03M 13/616; H04L 1/0043; H04L 1/0052; H04L 1/0058

(57) ABSTRACT

Provided are a method and apparatus for processing information. The apparatus includes: one or more memories, configured to store parameters of one basic parity check matrix set; and one or more processors, configured to encode information bits to be encoded or decode data to be decoded using the basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0−1, j0+1, . . . , L−1.

### TECHNICAL FIELD

The present disclosure relates to the field of communications, and in particular to a method and apparatus for processing information.

### BACKGROUND

As shown in FIG. 1, currently, a digital communication system can be generally divided into three parts: a sending end, a channel and a receiving end. The sending end usually includes a source, a channel encoder, a modulator (or write-in unit) and other parts. The receiving end usually includes a demodulator (or read-out unit), a channel decoder and a destination. The channel (or storage medium) exists between the sending end and the receiving end, and a noise source exists in the channel. A channel encoding link (including channel encoding/decoding, modulation/demodulation and the like) is the key of an entire digital communication physical layer, which decides the efficiency and reliability of underlying transmission of the digital communication system.

A main function of the channel encoder is to fight against the influence on useful signals caused by various noises and interferences in the channel. By manually adding some pieces of redundant information, the system is enabled to have a capability of automatically correcting an error, thereby guaranteeing the reliability of information transmission. In the related art, there have already been multiple channel codes such as a Low Density Parity Check (LDPC) code, a turbo code, a convolution code and a Reed-Solomon (RS) code. Various experiments and theories have proven that the LDPC code is a channel code, having most excellent performances, under an Additive White Gaussian Noise (AWGN) channel, the performances approaching the Shannon limit. The LDPC code is a linear block code which can be defined by a low density parity check matrix or a bipartite graph, and low-complexity encoding and decoding can be achieved by utilizing the sparsity of the check matrix thereof, thereby making LDPC become practical.

From a perspective of performances, the performances of the LDPC code are excellent. However, from a perspective of hardware complexity, the hardware complexity of the LDPC code is very high due to the fact that LDPC decoding is an iterative decoding process. Moreover, the LDPC code is a linear block code, and therefore there is a lack of certain flexibility in design of code rates and code lengths. In an 802.16e standard, in order to provide certain flexibility in terms of the code lengths and the code rates, 19 code lengths are supported, four code rates (1/2, 2/3, 3/4 and 5/6) are supported, and it is needed to adopt six check matrices for implementation. In an 802.11ad standard, four check matrices are adopted, and an encoding solution for four fixed code lengths and different code rates is provided. In an 802.11n/ac standard, 12 check matrices are adopted, and an encoding solution for four code rates and three code lengths is provided. For each one among the above standards, check matrices of a plurality of LDPC codes are needed to support the requirement on flexibility. Due to the fact that the check matrices corresponding to different code rates are not associated substantially, for a receiving decoding end, a plurality of decoders are needed to correspondingly decode each code rate or one decoder supporting the requirements of the multiple check matrices needs to be adopted. Regardless of which method is adopted, the hardware cost is high, and it is inconvenient to specifically optimize some units in the decoder.

An effective solution has not been proposed yet currently for the problems in the related art that an LDPC encoding/decoding system is high in hardware complexity and low in flexibility.

### SUMMARY

The embodiments of the present disclosure provide a method and apparatus for processing information, which are intended to at least solve the problems in the related art that an LDPC encoding/decoding system is high in hardware complexity and low in flexibility.

According to one aspect of the embodiments of the present disclosure, an apparatus for processing information is provided, which may include: one or more memories, configured to store parameters of one basic parity check matrix set; and one or more processors, configured to encode information bits to be encoded or decode data to be decoded using the basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0−1, j0+1, . . . , L−1.

In an exemplary embodiment, a dimension of each basic parity check matrix in the basic parity check matrix set may be Mb×Nb, the number of columns Nb may be a fixed value nb0, the number of rows Mb may be mbi, and each mbi may correspond to one code rate ri, where ri is a real number between 0 and 1, i=0, 1, 2, . . . , L−1, mbi is an integer greater than 0, and nb0 is an integer greater than 0.

In an exemplary embodiment, each of the short loops-4 may be constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b.

In an exemplary embodiment, a set Scj1 constituted by non-minus-one elements in a c^{th} column in the basic parity check matrix Hbⱼ₁, among all the basic parity check matrices in the basic parity check matrix set except the Hbⱼ₀, from top to bottom may be a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, MaxW is a positive integer, and c is an integer which is greater than or equal to 0 and is smaller than nb0.

In an exemplary embodiment, a top-to-bottom sequence of all elements in the set Scj1 may be identical to a top-to-bottom sequence of these elements in the set Scj0.

In an exemplary embodiment, each basic parity check matrix Hbi in the basic parity check matrix set may be equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

In an exemplary embodiment, the number of minus-one elements on different rows of the system bit part matrix of each basic parity check matrix in the basic parity check matrix set may be equal or has a difference smaller than or equal to 2.

In an exemplary embodiment, more than two or three continuous minus-one elements may not exist on each column of the system bit part matrix of each basic parity check matrix in the basic parity check matrix set.

In an exemplary embodiment, more than two or three continuous minus-one elements may not exist on each row of the system bit part matrix in the basic parity check matrix set.

In an exemplary embodiment, the value of nb0 may include: 8, 16, 24, 32, 40 or 48.

In an exemplary embodiment, the condition that the short loops-4 in the Hbⱼ₁ are the same as the short loops-4 in the Hbⱼ₀ may include that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner.

In an exemplary embodiment, any four elements [h_{ac}, h_{bc}, h_{bd}, h_{ad}] which are able to constitute a loop-4 in each basic parity check matrix of the basic parity check matrix set may satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d.

In an exemplary embodiment, the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 may be minimum, where % is a modulo operator, zf is an expansion factor, a, b, c, i, j and k are any integers which are greater than or equal to 0 and are smaller than nb0, a≠b≠c, and i≠j≠k.

In an exemplary embodiment, a basic parity check matrix of which the number of matrix rows, j, is smaller than a maximum column weight MaxW in the basic parity check matrix set may be equal to a matrix constituted by last j rows of the Hbⱼ₀, where the Hbⱼ₀ is a basic parity check matrix of which the number of matrix rows is equal to the maximum column weight MaxW, and MaxW and j are positive integers.

In an exemplary embodiment, one or more elements among any four elements [hₐᵢ, h_{bi}, h_{bj}, hₐⱼ] constituting a loop-4 in all basic parity check matrices of the basic parity check matrix set may belong to elements of which column weights are 2, and may satisfy an inequality (hₐᵢ−h_{bi}+h_{bj}−hₐⱼ)% zf≠0; and one or more elements among any six elements └hₐᵢ, h_{bi}, h_{bj}, h_{cj}, h_{ck}, hₐₖ┘ constituting a short loop-6 in all basic parity check matrices of the basic parity check matrix set may belong to elements of which column weights are 2, and may satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an exemplary embodiment, the value of ri is [½, ⅝, ¾, 13/16], i=0, 1, 2, 3, any four elements [hₐᵢ, h_{bi}, h_{bj}, hₐⱼ], constituting a loop-4 in a basic parity check matrix Hb0 of which a corresponding code rate r0=1/2 may all satisfy an inequality (hₐᵢ−h_{bi}+h_{bj}−hₐⱼ)% zf≠0; and any six elements └hₐᵢ, h_{bi}, h_{bj}, h_{cj}, h_{ck}, hₐₖ┘ constituting a short loop-6 in the basic parity check matrix Hb0 may all satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an exemplary embodiment, the one or more processors may encode the information bits to be encoded or decode the data to be decoded by means of the following modes: determining a block of the information bits to be encoded or a block of the data to be decoded, selecting a basic parity check matrix from the basic parity check matrix set according to the block of the information bits to be encoded or the block of the data to be decoded, and encoding the block of the information bits to be encoded or decoding the block of the data to be decoded based on the selected basic parity check matrix.

According to another aspect of the embodiments of the present disclosure, a method for processing information is provided, which may include that: information bits to be encoded or data to be decoded are acquired; and the information bits to be encoded are encoded or the data to be decoded are decoded using a pre-set basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0+1, j0+1, . . . , L−1.

In an exemplary embodiment, a dimension of each basic parity check matrix in the basic parity check matrix set may be Mb×Nb, the number of columns Nb may be a fixed value nb0, the number of rows Mb may be mbi, and each mbi may correspond to one code rate ri, where ri is a real number greater than 0, 1=0, 1, 2, . . . , L−1, mbi is an integer greater than 0, and nb0 is an integer greater than 0.

In an exemplary embodiment, each of the short loops-4 may be constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b.

In an exemplary embodiment, a set Scj1 constituted by non-minus-one elements in a c^{th} column in the basic parity check matrix Hbⱼ₁, among all the basic parity check matrices in the basic parity check matrix set except the Hbⱼ₀, from top to bottom may be a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, MaxW is a positive integer, and c is an integer which is greater than or equal to 0 and is smaller than nb0.

In an exemplary embodiment, a top-to-bottom sequence of all elements in the set Scj1 may be identical to a top-to-bottom sequence of these elements in the set Scj0.

In an exemplary embodiment, each basic parity check matrix Hbi in the basic parity check matrix set may be equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

In an exemplary embodiment, the number of minus-one elements on different rows of the system bit part matrix of each basic parity check matrix in the basic parity check matrix set may be equal or has a difference smaller than or equal to 2.

In an exemplary embodiment, more than two or three continuous minus-one elements may not exist on each column of the system bit part matrix of each basic parity check matrix in the basic parity check matrix set.

In an exemplary embodiment, more than two or three continuous minus-one elements may not exist on each row of the system bit part matrix in the basic parity check matrix set.

In an exemplary embodiment, the value of nb0 may include: 8, 16, 24, 32, 40 or 48.

In an exemplary embodiment, the condition that the short loops-4 in the Hbⱼ₁ are the same as the short loops-4 in the Hbⱼ₀ may include that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner.

In an exemplary embodiment, any four elements [h_{ac}, h_{bc}, h_{bd}, h_{ad}] which are able to constitute a loop-4 in each basic parity check matrix of the basic parity check matrix set may satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d.

In an exemplary embodiment, the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 may be minimum, where % is a modulo operator, zf is an expansion factor, a, b, c, i, j and k are any integers which are greater than or equal to 0 and are smaller than nb0, a≠b≠c, and i≠j≠k.

In an exemplary embodiment, a basic parity check matrix of which the number of matrix rows, j, is smaller than a maximum column weight MaxW in the basic parity check matrix set may be equal to a matrix constituted by last j rows of the Hbⱼ₀, where the Hbⱼ₀ is a basic parity check matrix of which the number of matrix rows is equal to the maximum column weight MaxW, and MaxW and j are positive integers.

In an exemplary embodiment, one or more elements among any four elements [hₐᵢ, h_{bi}, h_{bj}, hₐⱼ] constituting a loop-4 in all basic parity check matrices of the basic parity check matrix set may belong to elements of which column weights are 2, and may satisfy an inequality (hₐᵢ−h_{bi}+h_{bj}−hₐⱼ)% zf≠0; and one or more elements among any six elements └hₐᵢ, h_{bi}, h_{bj}, h_{cj}, h_{ck}, hₐₖ┘ constituting a short loop-6 in all basic parity check matrices of the basic parity check matrix set may belong to elements of which column weights are 2, and may satisfy an inequality (hₐ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an exemplary embodiment, the value of ri is [½, ⅝, ¾, 13/16], i=0, 1, 2, 3, any four elements [hₐᵢ, h_{bi}, h_{bj}, hₐⱼ] constituting a loop-4 in a basic parity check matrix Hb0 of which a corresponding code rate r0=1/2 may all satisfy an inequality (hₐᵢ−h_{bi}+h_{bj}−hₐⱼ)% zf≠0; and any six elements └hₐᵢ, h_{bi}, h_{bj}, h_{cj}, h_{ck}, hₐₖ┘ constituting a short loop-6 in the basic parity check matrix Hb0 may all satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an exemplary embodiment, the step that the information bits to be encoded are encoded or the data to be decoded are decoded using the pre-set basic parity check matrix set Hb may include that: a block of the information bits to be encoded or a block of the data to be decoded is determined, a basic parity check matrix is selected from the basic parity check matrix set according to the block of the information bits to be encoded or the block of the data to be decoded, and the block of the information bits to be encoded are encoded or the block of the data to be decoded are decoded based on the selected basic parity check matrix.

By means of the embodiments of the present disclosure, when LDPC encoding/decoding is adopted, a plurality of check matrices corresponding to a plurality of code rates are associated, so that encoding or decoding operation can be performed using the same encoder or decoder, the problems of high hardware complexity and low flexibility are solved, the hardware complexity is reduced, and the flexibility in encoding/decoding operation is improved.

### BRIEF DESCRIPTION OF THE DRAWINGS

The drawings illustrated herein are intended to provide further understanding of the present disclosure, and constitute a part of the present disclosure. The schematic embodiments and illustrations of the present disclosure are intended to explain the present disclosure, and do not form improper limits to the present disclosure. In the drawings:

FIG. 1 is a structural diagram of a digital communication system according to the related art;

FIG. 2 is a structural diagram of an apparatus for processing information according to an embodiment of the present disclosure;

FIG. 3 is a block diagram of a simple communication link model in an embodiment of the present disclosure;

FIG. 4 is a block diagram related to encoding of an LDPC code according to an embodiment of the present disclosure;

FIG. 5 is a block diagram related to decoding of an LDPC code according to an embodiment of the present disclosure;

FIG. 6 is a flowchart of a method for processing information according to an embodiment of the present disclosure;

FIG. 7 is a flowchart related to encoding of an LDPC code according to an embodiment of the present disclosure;

FIG. 8 is a flowchart related to decoding of an LDPC code according to an embodiment of the present disclosure;

FIG. 9 shows a structure of a basic parity check matrix of an LDPC code according to an embodiment of the present disclosure;

FIG. 10 is a diagram illustrating occurrence of loop-4 in a bipartite graph of an LDPC code in an embodiment of the present disclosure;

FIG. 11 is a diagram illustrating occurrence of loop-6 in a bipartite graph of an LDPC code in an embodiment of the present disclosure;

FIG. 12 is a diagram illustrating occurrence of loop-4 in a basic parity check matrix of an LDPC code in an embodiment of the present disclosure;

FIG. 13 is a diagram illustrating occurrence of loop-6 in a basic parity check matrix of an LDPC code in an embodiment of the present disclosure; and

FIG. 14 is a diagram of an expansion check matrix of an LDPC uniquely determined by a basic matrix, an expansion factor and a permutation matrix in an embodiment of the present disclosure.

### DETAILED DESCRIPTION OF THE EMBODIMENTS

The present disclosure will be illustrated below with reference to the drawings and the embodiments in detail. It is important to note that the embodiments of the present disclosure and the characteristics in the embodiments can be mutually combined under the condition of no conflicts.

According to an embodiment of the present disclosure, an apparatus for processing information is provided.

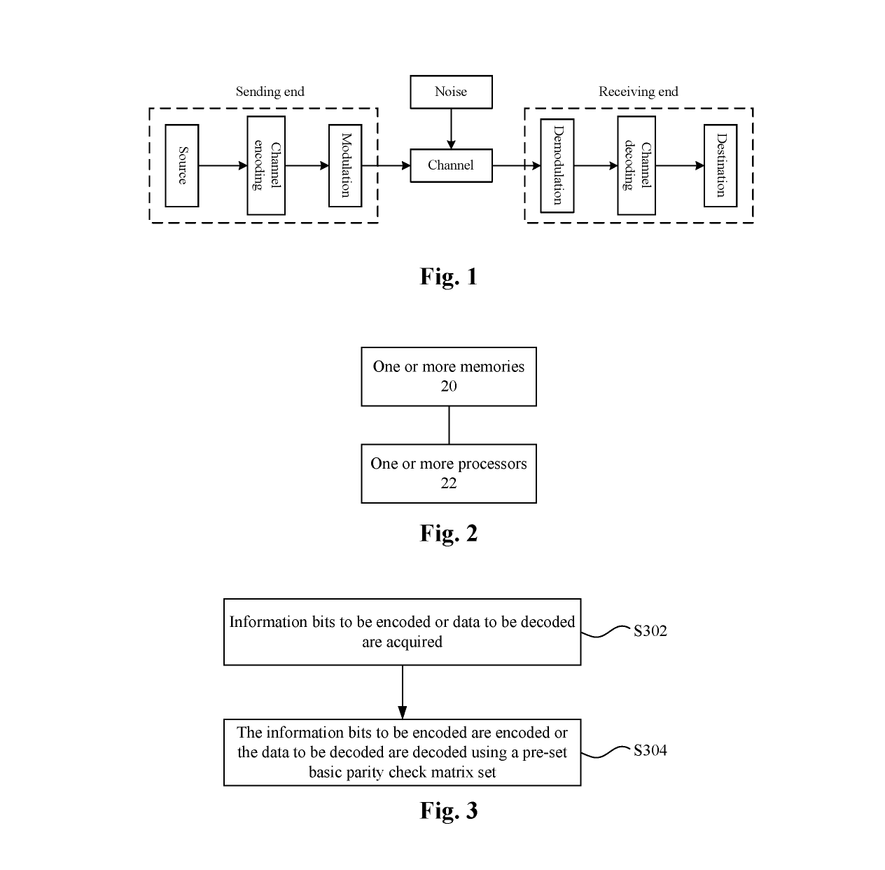

FIG. 2 is a structural diagram of an apparatus for processing information according to an embodiment of the present disclosure. As shown in FIG. 2, the apparatus for processing information according to the embodiment of the present disclosure mainly includes: one or more memories 20, configured to store parameters of one basic parity check matrix set; and one or more processors 22, configured to encode information bits to be encoded or decode data to be decoded using the basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0+1, j0+1, . . . , L−1.

In an optional implementation of the embodiment of the present disclosure, a dimension of each basic parity check matrix in the basic parity check matrix set is Mb×Nb, the number of columns Nb is a fixed value nb0, the number of rows Mb is mbi, and each mbi corresponds to one code rate ri, where ri is a real number between 0 and 1, i=0, 1, 2, . . . , L−1, mbi is an integer greater than 0, and nb0 is an integer greater than 0.

In an optional implementation of the embodiment of the present disclosure, each of the short loops-4 is constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b.

In an optional implementation of the embodiment of the present disclosure, a set Scj1 constituted by non-minus-one elements in a c^{th} column in the basic parity check matrix Hbⱼ₁, among all the basic parity check matrices in the basic parity check matrix set except the Hbⱼ₀, from top to bottom is a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, j0 is an integer between 0 and L−1, MaxW is a positive integer, and c is an integer which is greater than or equal to 0 and is smaller than nb0. In the embodiments, the column weight refers to the number of non-minus-one elements in a column in a basic check matrix.

In an optional implementation of the embodiment of the present disclosure, a top-to-bottom sequence of all elements in the set Scj1 is identical to a top-to-bottom sequence of these elements in the set Scj0.

In an optional implementation of the embodiment of the present disclosure, each basic parity check matrix Hbi in the basic parity check matrix set is equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

In an optional implementation of the embodiment of the present disclosure, the number of minus-one elements on different rows of the system bit part matrix of each basic parity check matrix in the basic parity check matrix set is equal or has a difference smaller than or equal to 2.

In an optional implementation of the embodiment of the present disclosure, more than two or three continuous minus-one elements do not exist on each column of the system bit part matrix of each basic parity check matrix in the basic parity check matrix set.

In an optional implementation of the embodiment of the present disclosure, more than two or three continuous minus-one elements do not exist on each row of the system bit part matrix in the basic parity check matrix set.

In an optional implementation of the embodiment of the present disclosure, the value of nb0 includes, but is not limited to, 8, 16, 24, 32, 40 or 48.

In an optional implementation of the embodiment of the present disclosure, the condition that the short loops-4 in the Hbⱼ₁ are the same as the short loops-4 in the Hbⱼ₀ includes that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner. That is, four elements of each short loop-4 in the matrix Hbⱼ₁ are equal to four elements of each short loop-4 in the matrix Hbⱼ₀; two elements of each short loop-4 on a row in the Hbⱼ₁ are also on a row in the Hbⱼ₀; and two elements of each short loop-4 on a column in the Hbⱼ₁ are also on a column in the Hbⱼ₀.

In an optional implementation of the embodiment of the present disclosure, any four elements [h_{ac}, h_{bc}, h_{bd}, h_{ad}] which are able to constitute a loop-4 in each basic parity check matrix of the basic parity check matrix set satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d. In this embodiment, the expansion factor zf is a dimension of a permutation matrix (general unit matrix), and the value of zf should be greater than 0.

In an optional implementation of the embodiment of the present disclosure, the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 is minimum, where % is a modulo operator, zf is an expansion factor, a, b, c, i, j and k are any integers which are greater than or equal to 0 and are smaller than nb0, a≠b≠c, and i≠j≠k.

In an optional implementation of the embodiment of the present disclosure, a basic parity check matrix of which the number of matrix rows, j, is smaller than a maximum column weight MaxW in the basic parity check matrix set is equal to a matrix constituted by last j rows of the Hbⱼ₀, where the Hbⱼ₀ is a basic parity check matrix of which the number of matrix rows is equal to the maximum column weight MaxW, and MaxW and j are positive integers.

In an optional implementation of the embodiment of the present disclosure, one or more elements among any four elements [hₐᵢ, h_{bi}, h_{bj}, hₐⱼ] in all basic parity check matrices of the basic parity check matrix set belong to elements of which column weights are 2, and satisfy an inequality (hₐᵢ−h_{bi}+h_{bj}−hₐⱼ)% zf≠0; and one or more elements among any six elements └hₐᵢ, h_{bi}, h_{bj}, h_{cj}, h_{ck}, hₐₖ┘ constituting a short loop-6 in all basic parity check matrices of the basic parity check matrix set belong to elements of which column weights are 2, and satisfy an inequality (hₐᵢ−h_{bi}+h_{bj}+h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an optional implementation of the embodiment of the present disclosure, the value of ri is [½, ⅝, ¾, 13/16], i=0, 1, 2, 3, any four elements [hₐᵢ, h_{bi}, h_{bj}, hₐⱼ] constituting a loop-4 in a basic parity check matrix Hb0 of which a corresponding code rate r0=½ all satisfy an inequality (hₐᵢ−h_{bi}+h_{bj}−hₐⱼ)% zf≠0; and any six elements └hₐᵢ, h_{bi}, h_{bj}, h_{cj}, h_{ck}, hₐₖ┘ constituting a short loop-6 in the basic parity check matrix Hb0 all satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c, and i≠j≠k.

In an optional implementation of the embodiment of the present disclosure, the one or more processors encode the information bits to be encoded or decode the data to be decoded by means of the following modes: determining a block of the information bits to be encoded or a block of the data to be decoded, selecting a basic parity check matrix from the basic parity check matrix set according to the block of the information bits to be encoded or the block of the data to be decoded, and encoding the block of the information bits to be encoded or decoding the block of the data to be decoded based on the selected basic parity check matrix.

By means of the above apparatus for processing information provided by the embodiments of the present disclosure, code rates which can be supported by an LDPC code are R₀, R₁, . . . , R_{L-1}, corresponding basic parity check matrices are Hb₀, Hb₁, Hb_{(L-1)}, the number of rows of the basic parity check matrices is respectively M₀, M₁, . . . , M_{L-1}, the number of columns for each of the basic parity check matrices is Nb, L is the number of code rates to be constructed, and each basic parity check matrix is configured, so that encoding or decoding operation can be performed using the same encoder or decoder, the problems of high hardware complexity and low flexibility are solved, the hardware complexity is reduced, and the flexibility in encoding/decoding operation is improved.

According to an embodiment of the present disclosure, a method for processing information is provided, which may be implemented by means of the above apparatus for processing information.

FIG. 3 is a flowchart of a method for processing information according to an embodiment of the present disclosure. As shown in FIG. 3, the method mainly includes Step S302 to Step S304 as follows.

Step S302: Information bits to be encoded or data to be decoded are acquired.

Step S304: The information bits to be encoded are encoded or the data to be decoded are decoded using a pre-set basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0−1, j0+1, . . . , L−1.

In an optional implementation solution, a dimension of each basic parity check matrix in the basic parity check matrix set is Mb×Nb, the number of columns Nb is a fixed value nb0, the number of rows Mb is mbi, and each mbi corresponds to one code rate ri, where ri is a real number greater than 0, i=0, 1, 2, . . . , L−1, mbi is an integer greater than 0, and nb0 is an integer greater than 0.

In the optional implementation solution, each of the short loops-4 is constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b.

In an optional implementation solution, a set Scj1 constituted by non-minus-one elements in a c^{th} column in the basic parity check matrix Hbⱼ₁, among all the basic parity check matrices in the basic parity check matrix set except the Hbⱼ₀, from top to bottom is a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, MaxW is a positive integer, and c is an integer which is greater than or equal to 0 and is smaller than nb0.

In an optional implementation solution, a top-to-bottom sequence of all elements in the set Scj1 is identical to a top-to-bottom sequence of these elements in the set Scj0.

In an optional implementation solution, each basic parity check matrix Hbi in the basic parity check matrix set is equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

In an optional implementation solution, the number of minus-one elements on different rows of the system bit part matrix of each basic parity check matrix in the basic parity check matrix set is equal or has a difference smaller than or equal to 2.

In an optional implementation solution, more than two or three continuous minus-one elements do not exist on each column of the system bit part matrix of each basic parity check matrix in the basic parity check matrix set.

In an optional implementation solution, more than two or three continuous minus-one elements do not exist on each row of the system bit part matrix in the basic parity check matrix set.

In an optional implementation solution, the value of nb0 includes, but is not limited to, 8, 16, 24, 32, 40 or 48.

In an optional implementation solution, the condition that the short loops-4 in the Hbⱼ₁ are the same as the short loops-4 in the Hbⱼ₀ includes that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner.

In an optional implementation solution, any four elements [h_{ac}, h_{bc}, h_{bd}, h_{ad}] which are able to constitute a loop-4 in each basic parity check matrix of the basic parity check matrix set satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d.

In an optional implementation solution, the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 is minimum, where % is a modulo operator, zf is an expansion factor, a, b, c, i, j and k are any integers which are greater than or equal to 0 and are smaller than nb0, a≠b≠c, and i≠j≠k.

In an optional implementation solution, a basic parity check matrix of which the number of matrix rows, j, is smaller than a maximum column weight MaxW in the basic parity check matrix set is equal to a matrix constituted by last j rows of the Hbⱼ₀, where the Hbⱼ₀ is a basic parity check matrix of which the number of matrix rows is equal to the maximum column weight MaxW, and MaxW and j are positive integers.

In an optional implementation solution, one or more elements among any four elements [hₐᵢ, h_{bi}, h_{bj}, hₐⱼ] constituting a loop-4 in all basic parity check matrices of the basic parity check matrix set belong to elements of which column weights are 2, and satisfy an inequality (hₐᵢ−h_{bi}+h_{bj}−hₐⱼ)% zf≠0; and one or more elements among any six elements └hₐᵢ, h_{bi}, h_{bj}, h_{ck}, hₐₖ┘ constituting a short loop-6 in all basic parity check matrices of the basic parity check matrix set belong to elements of which column weights are 2, and satisfy an inequality (hₐᵢ−h_{bi}+h_{bj}−h_{cj}+h_{ck}−hₐₖ)% zf≠0.

In an optional implementation solution, the value of ri is [½, ⅝, ¾, 13/16], i=0, 1, 2, 3, any four elements [hₐᵢ, h_{bi}, h_{bj}, hₐⱼ], constituting a loop-4 in a basic parity check matrix Hb0 of which a corresponding code rate r0=½ all satisfy an inequality (hₐᵢ−h_{bi}+h_{bj}−h_{cj}+h_{ck}−hₐₖ)% zf≠0; and any six elements └hₐᵢ, h_{bi}, h_{bj}, h_{cj}, h_{ck}, hₐₖ┘ constituting a short loop-6 in the basic parity check matrix Hb0 all satisfy an inequality (hₐᵢ−h_{bi}+h_{bj}−h_{cj}+h_{ck}−hₐₖ)% zf≠0.

In an optional implementation solution, the step that the information bits to be encoded are encoded or the data to be decoded are decoded using the pre-set basic parity check matrix set Hb includes that: a block of the information bits to be encoded or a block of the data to be decoded is determined, a basic parity check matrix is selected from the basic parity check matrix set according to the block of the information bits to be encoded or the block of the data to be decoded, and the block of the information bits to be encoded are encoded or the block of the data to be decoded are decoded based on the selected basic parity check matrix.

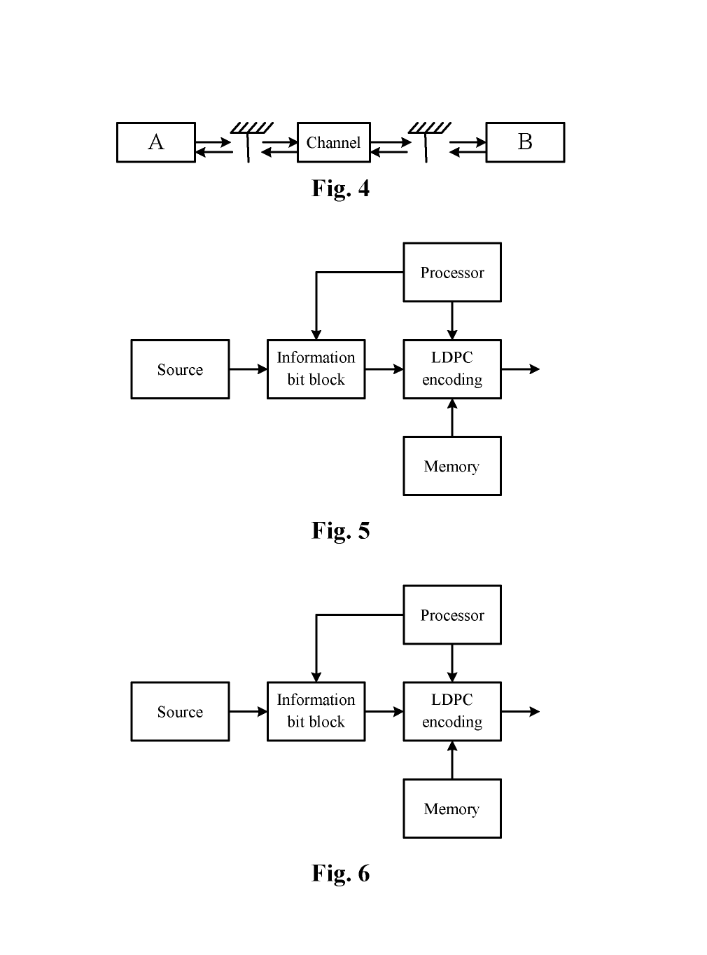

In order to further understand the solution provided by the embodiments of the present disclosure, the solution will be described below by taking a simple communication link model shown in FIG. 4 as an example.

FIG. 4 shows a simple communication link model. Information may be transmitted from an end A to an end B, or may be transmitted from the end B to the end A. The end A and the end B may be one or more types of devices such as a base station, a relay node, an access node and a terminal device, or a plurality of devices in the same device type. Data may be transmitted between the end A and the end B at any time, or data communication may be performed only when conditions allow. The apparatus for processing information provided by the embodiment of the present disclosure can be applied to any data transmission from the end A to the end B and from the end B to the end A.

In a communication link shown in FIG. 4, it can be seen that the end A may be equipped with t1 transmitting antennae and r1 receiving antennae, and the end B may also be equipped with t2 transmitting antennae and r2 receiving antennae. Generally, in the end A, t1≧1, and r1≧1; and in the end B, t2≧1, and r2≧1. The antennae of the end A may be fixed or movable; and meanwhile, the antennae of the end B may be fixed or movable.

In the communication link shown in FIG. 4, it is needed to perform communication transmission between the end A and the end B via a channel. The channel may be a wireless channel such as a microwave communication channel, an electromagnetic wave communication channel, a sound wave communication channel and an optical communication channel; the channel may also be a wired channel such as an optical fibre communication channel and a cable; or the channel may also be various storage media.

For simplicity, illustrations are made herein by taking sending of data information from a device al of the end A to a certain device b1 of the end B as an example. In this case, the al needs to read data from a source via a processor, form the data into a block, process (encode or modulate) the data block, and then transmit the data block via a transmitting antenna. A processor of the certain device b1 of the end B needs to receive a signal from a receiving antenna and process the signal to obtain original data. Conversely, a principle of data transmission from the end B to the end A is the same as the above.

In the above link communication or system communication, an LDPC code can be adopted to improve the reliability of data transmission. The LDPC code is a linear block code which can be defined by a very low density parity check matrix or a bipartite graph.

An encoder of the end A or the end B is shown in FIG. 5, and a decoder of the end A or the end B is shown in FIG. 6. Processors in the encoder/decoder are mainly responsible for various logical operations. As shown in FIG. 5, the processor in the encoder is mainly responsible for processing data, namely acquiring information to be sent from the source, forming information bits of the source into a block, performing LDPC encoding on an information bit block in cooperation with a memory, and then modulating and transmitting the information bit block. As shown in FIG. 6, the processor of the decoder acquires information from an antenna, configures a memory to perform LDPC decoding on the information, combines the information and then transmits the combined information to a destination. The memories of the encoder/decoder are mainly responsible for storing all pieces of data and program codes needed by the end A or the end B. That is, the memories are mainly responsible for storing information about a basic parity check matrix of the LDPC code and other pieces of data information.

As shown in FIG. 5, an LDPC encoder forms the information bits into one l×k information bit block represented by “a” here. The information bit block a is encoded by means of the encoder to obtain a l×n codeword bit block represented by “x” here. A basic matrix of the LDPC code is Hb, and a corresponding expansion check matrix is H.

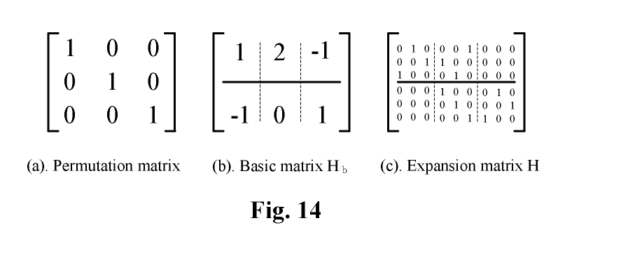

In this embodiment, the expansion check matrix H of the LDPC code is uniquely determined by the basic matrix Hb, an expansion factor zf and a permutation matrix. The permutation matrix is generally a zf×zf unit matrix. If a certain element value hᵢⱼ in the basic parity check matrix is equal to −1, the permutation matrix of this place is a zf×zf all-0 matrix, and if hᵢⱼ≠−1, the matrix of this place is a matrix obtained by rotate-right of the permutation matrix by hᵢⱼ. For example, in a specific example shown in FIG. 14, the expansion check matrix H of the LDPC code is determined by the basic matrix Hb (2×3), the expansion factor zf (=3) and the permutation matrix (3×3 unit matrix).

The LDPC code serves as a linear block code, the corresponding expansion check matrix is H, and the following relation can be satisfied for each codeword x:

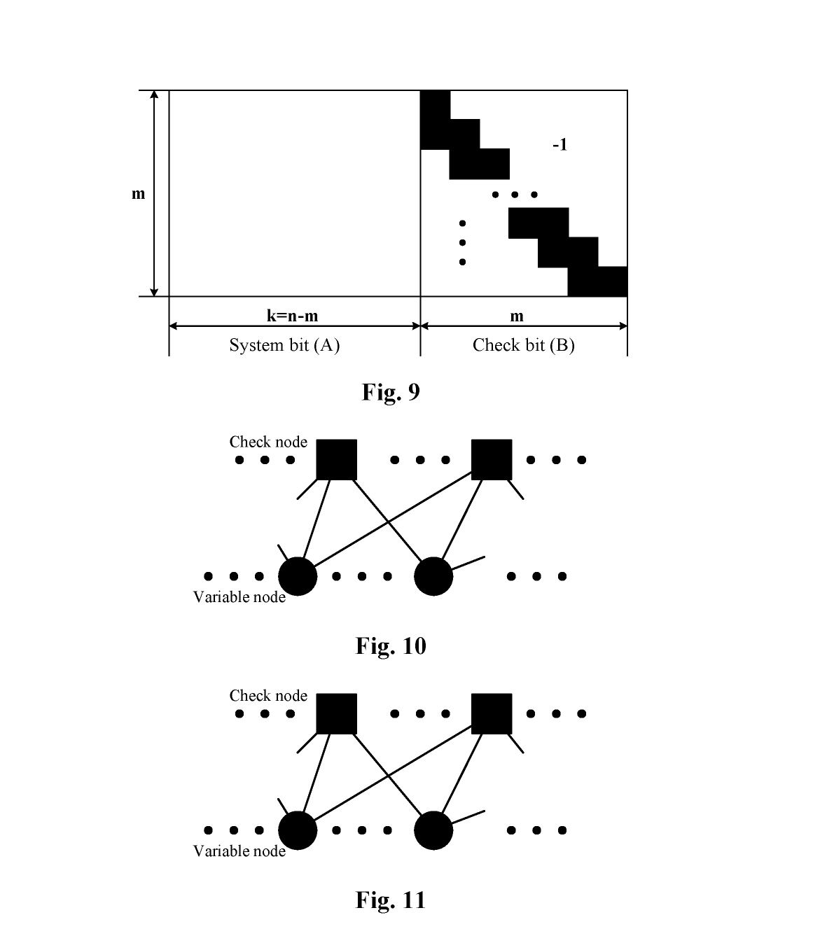

H×x^{T}=0^{T}

where ‘0’ here is an all-0 vector. Since all operations are executed on a binary field, all addition and subtraction operations here are exclusive-or operations, and multiplication operations are AND operations. According to the relation, the expansion check matrix H can be divided into two parts: a system bit part matrix A and a check bit part matrix B, as shown in FIG. 9, that is,

H=[AB].

Meanwhile, an LDPC codeword x is divided into a system bit part vector a and a check bit part vector b as follows:

x=[ab].

The following relation can be obtained:

A×a^{T}=B×b^{T}.

It can be seen that it is only needed to calculate a check part b. Since the matrix B can be specially processed and can be designed, for example, into a lower triangular structure or a double lower triangular structure, the check part b can be obtained by simple calculation. Then, an information part a and the check part b are combined, namely c=[a b], to obtain the LDPC codeword x.

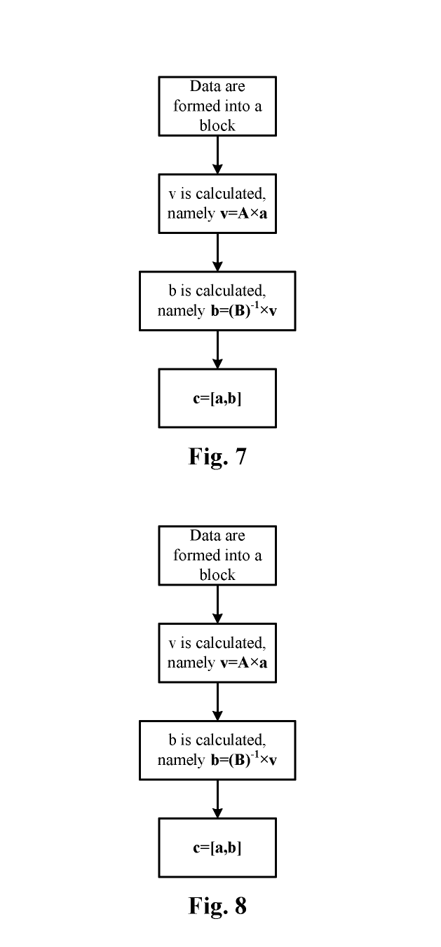

FIG. 7 shows a flowchart of LDPC encoding corresponding to an encoder. As shown in FIG. 7, LDPC encoding in the present embodiment mainly includes Step 1 to Step 4 as follows.

Step 1: Data to be encoded are formed into one 1×k information bit block namely a.

Step 2: v is calculated, namely v=A×a.

Step 3: b is calculated, namely b=(B)⁻¹×a, to obtain a check part.

Step 4: The information part a and the check part b are combined, namely c=[a b], to obtain an LDPC codeword x.

In an LDPC decoder, two modules namely a processor (e.g., a Central Processing Unit (CPU)) and a memory are also needed. The processor is mainly responsible for various logical operations, and the memory is mainly responsible for storing information about a basic parity check matrix of an LDPC code and storing other pieces of decoded data information. The LDPC decoder is shown in FIG. 6.

There are multiple LDPC decoding methods such as a probability domain Belief Propagation (BP) decoding algorithm, a log domain BP decoding algorithm and a layered min-sum decoding algorithm. The performance of the probability domain BP decoding algorithm is optimal. But the probability domain BP decoding algorithm has the disadvantages that since a great amount of multiplication operations are involved and the operation burden are heavy, the needed hardware cost is very high, the dynamic range of a numerical value is large, and the stability is low. Thus, the probability domain BP decoding algorithm cannot be used in practical application generally. Compared with the probability domain BP decoding algorithm, the log domain BP decoding algorithm reduces many calculation units, but many multiplication operations are still needed, and therefore the needed hardware cost is not low. The layered min-sum decoding algorithm converts key calculation (log operation and multiplication operation) units of the log domain BP decoding algorithm into calculation of a minimum value and a secondary minimum value, and therefore the needed hardware resources are greatly reduced. Although there is a little loss in performance, many hardware resources can be reduced. Thus, the layered min-sum decoding algorithm is more frequently adopted in practical application.

For any decoding methods, it is needed to perform iterative decoding. A decoding module is mainly divided into two parts: a check node updating module and a variable node updating module. The LDPC decoder is shown in FIG. 6, and a corresponding flowchart for LDPC decoding is shown in FIG. 8. As shown in FIG. 8, LDPC decoding mainly includes Step 1 to Step 4 as follows.

Step 1: Initialization is performed.

Step 2: A check node is updated.

Step 3: A variable node is updated.

Step 4: An inequality H×s==0|Iter>maxis judged, if so, the operation is ended, and otherwise, Step 2 is returned.

In LDPC encoding and decoding, whether or not characteristics such as excellent performance, high throughput, high flexibility and low complexity can be obtained is closely related to a designed LDPC code check matrix. Conversely, if the designed LDPC code check matrix is not appropriate enough, the performance of the LDPC encoding and decoding will be reduced, and meanwhile, the complexity and the flexibility may be influenced. Thus, how to obtain an appropriate LDPC code check matrix is very important.

In order to better understand the idea of the embodiments of the present disclosure, the situation of the constitution of girth by, e.g., short loops-4 and short loops-6, in a basic parity check matrix of an LDPC code will be introduced below.

In the basic parity check matrix, the necessary and sufficient conditions for the existence of girth=4 in a short loop-4 are that: in a basic matrix, any four elements [hₐᵢ, h_{bi}, h_{bj}, hₐⱼ] which are able to constitute a loop-4 satisfy:

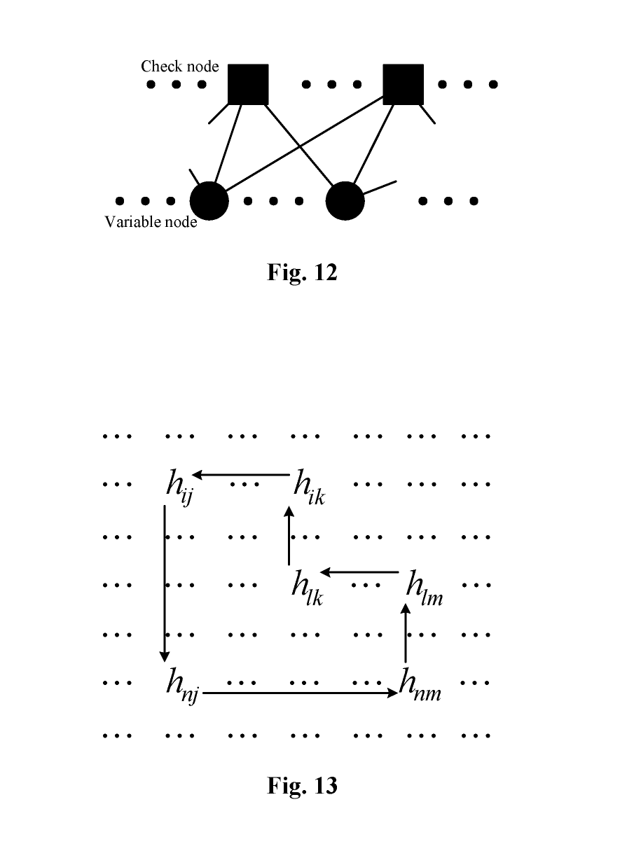

(hₐᵢ−h_{bi}+h_{bj}−hₐⱼ)% zf==0,

where zf is an expansion factor, the situation of girth=4 will occur between the elements at the four positions, and expressions in a bipartite graph are shown in FIG. 10. Thus, since information is only exchanged and transferred between these four nodes (two variable nodes and two check nodes), after multiple iterations are performed, the final codeword performance will be reduced due to the fact that most pieces of continuously exchanged information come from information fed back by themselves and there is not enough external information. Expressions of these elements in the basic parity check matrix are shown in FIG. 12 specifically, and expressions in the bipartite graph are shown in FIG. 10. Consequently, when the basic parity check matrix of the LDPC code is designed, it is needed to make the above equality false, that is,

(hₐᵢ−h_{bi}+h_{bj}−hₐⱼ)% zf≠0.

In the basic parity check matrix, the necessary and sufficient conditions for the existence of girth=6 in a short loop-6 are that: in a basic matrix, any six elements └hₐᵢ, h_{bi}, h_{bj}, h_{cj}, h_{ck}, hₐₖ┘ which are able to constitute a loop-6 satisfy:

(hₐᵢ−h_{bi}+h_{bj}−h_{cj}+h_{ck}−hₐₖ)% zf=0,

where zf is an expansion factor, the situation of girth=6 will occur between the elements at the six positions, and expressions in a bipartite graph are shown in FIG. 9. Thus, due to the same reason as girth=4, since most pieces of information are exchanged and transferred between these six nodes (three variable nodes and three check nodes), there is not enough external information exchanged, and the final codeword performance will be reduced (which is better than that in the short loops-4 to some extent). Expressions of these elements in the basic parity check matrix are shown in FIG. 13 specifically, and expressions in the bipartite graph are shown in FIG. 11. Consequently, when the basic parity check matrix of the LDPC code is designed, it is needed to make the above equality false (or occur as infrequently as possible), that is,

(hₐᵢ−h_{bi}+h_{bj}−h_{cj}+h_{ck}−hₐₖ)% zf≠0.

In accordance with a construction method for a basic parity check matrix of an LDPC code having multiple code rates provided by the embodiments of the present disclosure, analysis is performed below by means of a specific embodiment. Two parts, namely a processor and a memory, are contained in the specific embodiment of the encoder/decoder. The processor is mainly responsible for various logical operations, and the memory is mainly responsible for storing various pieces of information, in particular, very important basic parity check matrices in LDPC encoding and decoding.

In the specific embodiment, the code rates are respectively R₀=1/2, R₁=5/8, R₂=3/4 and R₃=13/16, corresponding basic parity check matrices are respectively Hb₀, Hb₁, Hb₂ and Hb₃, and the number of columns is 16. The number of rows of the basic parity check matrix corresponding to respective code rates is (hₐᵢ−h_{bi}+h_{bj}−h_{cj}+h_{ck}−hₐₖ)% zf≠0. According to the above inventive content, these four basic parity check matrices are provided herein, an expansion factor zf is equal to 256, and a basic row weight is 4.

Basic parity check matrix Hb₀ corresponding to code rate R₀=13/16:

| | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| 0 | 43 | 141 | 79 | 205 | 74 | 246 | 107 | 85 | 136 | 232 | 38 | 198 | 69 | 163 | −1 | −1 |
| 1 | 26 | 105 | 137 | 72 | 159 | 32 | 172 | 122 | 224 | 187 | 39 | 51 | 76 | 219 | 239 | −1 |
| 2 | 110 | 4 | 77 | 11 | 157 | 107 | 123 | 162 | 240 | 89 | 196 | 211 | 175 | 117 | 225 | 0 |

Basic parity check matrix Hb₁ corresponding to code rate R₁=3/4:

| | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| 0 | 171 | 132 | 175 | 50 | 205 | 166 | 28 | 166 | 23 | 2 | 42 | 155 | 242 | −1 | −1 | −1 |
| 1 | 43 | 141 | 79 | 205 | 74 | 246 | 107 | 85 | 136 | 232 | 38 | 198 | 69 | 163 | −1 | −1 |
| 2 | 26 | 105 | 137 | 72 | 159 | 32 | 172 | 122 | 224 | 187 | 39 | 51 | 76 | 219 | 239 | −1 |
| 3 | 110 | 4 | 77 | 11 | 157 | 107 | 123 | 162 | 240 | 89 | 196 | 211 | 175 | 117 | 225 | 0 |

Basic parity check matrix Hb₂ corresponding to code rate R₂=5/8:

| | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| 0 | −1 | −1 | 175 | 50 | −1 | 166 | 28 | −1 | 23 | 2 | 42 | −1 | −1 | −1 | −1 | −1 |
| 1 | 171 | 132 | −1 | 205 | 205 | −1 | 107 | 166 | −1 | −1 | −1 | 155 | −1 | −1 | −1 | −1 |
| 2 | 43 | 141 | 79 | −1 | 74 | 246 | −1 | 85 | 136 | 232 | −1 | 198 | 242 | −1 | −1 | −1 |
| 3 | −1 | −1 | 137 | 72 | −1 | 32 | 172 | −1 | 224 | 187 | 38 | −1 | 69 | 163 | −1 | −1 |
| 4 | 26 | 105 | −1 | 11 | 159 | −1 | −1 | 122 | −1 | 89 | 39 | 51 | 76 | 219 | 239 | −1 |
| 5 | 110 | 4 | 77 | −1 | 157 | 107 | 123 | 162 | 240 | −1 | 196 | 211 | 175 | 117 | 225 | 0 |

Basic parity check matrix Hb₃ corresponding to code rate R₃=1/2:

| | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| 0 | 171 | −1 | 175 | −1 | 205 | −1 | 28 | −1 | 23 | −1 | −1 | −1 | −1 | −1 | −1 | −1 |
| 1 | 43 | −1 | 79 | −1 | 74 | −1 | 107 | −1 | 136 | 0 | −1 | −1 | −1 | −1 | −1 | −1 |
| 2 | −1 | 132 | −1 | 50 | −1 | 166 | −1 | 166 | −1 | 2 | 42 | −1 | −1 | −1 | −1 | −1 |
| 3 | −1 | 141 | −1 | 205 | −1 | 246 | −1 | 85 | −1 | 232 | 38 | 155 | −1 | −1 | −1 | −1 |
| 4 | 26 | −1 | 137 | −1 | 159 | −1 | 172 | −1 | 224 | −1 | 39 | 198 | 242 | −1 | −1 | −1 |
| 5 | 110 | −1 | 77 | −1 | 157 | −1 | 123 | −1 | 240 | −1 | 196 | −1 | 69 | 163 | −1 | −1 |
| 6 | −1 | 105 | −1 | 72 | −1 | 32 | −1 | 122 | −1 | 187 | −1 | 51 | 76 | 219 | 239 | −1 |
| 7 | −1 | 4 | −1 | 11 | −1 | 107 | −1 | 162 | −1 | 89 | −1 | 211 | 175 | 117 | 225 | 0 |

From all the above basic parity check matrices, it can be seen that the basic parity check matrices have characteristics as follows.

(1) From the check matrix, provided above, for all code rates, it can be seen that the numbers of columns of all basic parity check matrices are identical to 16, and corresponding check bit part matrices are strictly lower triangular structures.

(2) A maximum column weight MaxW is 4, and sets constituted by non-minus-one elements on the same column in other basic parity check matrices of which the number of matrix rows is greater than or equal to the maximum column weight 4 are equal.

(3) The maximum column weight MaxW is 4, and the number of rows of a basic parity check matrix Hb1 corresponding to a code rate R1=3/4 is equal to 4, so that the number of matrix rows of the other basic parity check matrice of which the number of matrix rows is smaller than the maximum column weight 4, such as a basic parity check matrix Hb0 corresponding to a code rate R0=13/16, is 3, and the basic parity check matrix is equal to a matrix constituted by last three rows of the Hb₁.

(4) In a system bit part matrix of the same basic parity check matrix, the number of minus-one elements on different rows is equal, such as the Hb0 and the Hb1; or, a maximum difference value is smaller than or equal to 2, such as Hb2 and Hb3.

(5) More than two or three continuous minus-one elements do not exist on the same row in the system bit part matrix of the same basic parity check matrix.

(6) More than two or three continuous minus-one elements do not exist on the same column in the system bit part matrix of the same basic parity check matrix.

(7) From the check matrix, provided above, for all code rates, it can be seen that more than 50 percent of all short loops-4 constituted in each of other basic parity check matrices, except the Hbⱼ₁, are the same as short loops-4 constituted in the Hbⱼ₁.

(8) In the basic parity check matrix, any four elements [h_{ac}, h_{bc}, h_{bd}, h_{ad}] which are able to constitute short loops-4 all satisfy an inequality (h_{ac}−h_{bc}+h_{bd}−h_{ad})% zf≠0, where % is a modulo operator, zf is an expansion factor, and zf=256.

(9) In the basic parity check matrix, any six elements └hₐᵢ, h_{bi}, h_{bj}, h_{cj}, h_{ck}, hₐₖ ┘ which are able to constitute short loops-6 all satisfy an inequality (hₐᵢ−h_{bi}+h_{bj}−h_{cj}+h_{ck}−hₐₖ)% zf≠0, or the number of short loops-6 satisfying the inequality is maximum, where % is a modulo operator, zf is an expansion factor, and zf=256.

From the above descriptions, by means of the technical solutions provided by the embodiments of the present disclosure, basic parity check matrices for all code rates are correlated, and the following benefits are achieved.

(1) The basic parity check matrices for all code rates can keep matrix short-loop characteristics consistent substantially. Thus, when the performance of one basic parity check matrix (in the present embodiment, a code rate is R₁=3/4) is quite excellent, it can be ensured that the performances of basic parity check matrices for other code rates will be good.

(2) The forms of the basic parity check matrices for all code rates are consistent substantially, so that the same decoder can be completely shared. Thus, hardware resources can be greatly reduced. It is unnecessary to waste a great number of resources to make a decoder for each code rate (check matrix) or it is unnecessary to greatly adjust a decoder to support other code rates.

Obviously, those skilled in the art shall understand that all modules or all steps in the present disclosure can be implemented by using a general calculation apparatus, can be centralized on a single calculation apparatus or can be distributed on a network composed of a plurality of calculation apparatuses. Optionally, they can be implemented by using executable program codes of the calculation apparatuses. Thus, they can be stored in a storage apparatus and executed by the calculation apparatuses, the shown or described steps can be executed in a sequence different from this sequence under certain conditions, or they are manufactured into each integrated circuit module respectively, or a plurality of modules or steps therein are manufactured into a single integrated circuit module. Thus, the present disclosure is not limited to a combination of any specific hardware and software.

The above is only the preferred embodiments of the present disclosure, and is not intended to limit the present disclosure. There can be various modifications and variations in the present disclosure for those skilled in the art. Any modifications, equivalent replacements, improvements and the like within the principle of the present disclosure shall fall within the protection scope defined by the appended claims of the present disclosure.

### INDUSTRIAL APPLICABILITY

In the embodiments of the present disclosure, when LDPC encoding/decoding operation is adopted, a plurality of check matrices corresponding to a plurality of code rates are associated, so that encoding or decoding operation can be performed using the same encoder or decoder, the problems of high hardware complexity and low flexibility are solved, the hardware complexity is reduced, and the flexibility in encoding/decoding operation is improved. The embodiments of the present disclosure have industrial practicality.

1. An apparatus for processing information, comprising:
one or more memories, configured to store parameters of one basic parity check matrix set; and
one or more processors, configured to encode information bits to be encoded or decode data to be decoded using the basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0−1, j0+1, . . . , L−1.

2. The apparatus as claimed in claim 1, wherein a dimension of each basic parity check matrix in the basic parity check matrix set is Mb×Nb, the number of columns Nb is a fixed value nb0, the number of rows Mb is mbi, and each mbi corresponds to one code rate ri, where ri is a real number between 0 and 1, i=0, 1, 2, . . . , L−1, mbi is an integer greater than 0, and nb0 is an integer greater than 0.

3. The apparatus as claimed in claim 2, wherein
each of the short loops-4 is constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b;
or
the value of nb0 comprises: 8, 16, 24, 32, 40 or 48;
or
the value of ri is [½, ⅝, ¾, 13/16], i=0, 1, 2, 3, any four elements [hₐᵢ, h_{bi}, h_{bj}, hₐⱼ] constituting a loop-4 in a basic parity check matrix Hb0 of which a corresponding code rate r0=1/2 all satisfy an inequality (hₐᵢ−h_{bi}+h_{bj}−hₐⱼ)% zf≠0; and any six elements └hₐᵢ, h_{bi}, h_{bj}, h_{cj}, h_{ck}, hₐₖ┘ constituting a short loop-6 in the basic parity check matrix Hb0 all satisfy an inequality (hₐᵢ−h_{bi}+h_{bj}−hₐⱼ)% zf≠0, where % is a modulo operator, zf is an expansion factor, a, b, c, i, j and k are any integers which are greater than or equal to 0 and are smaller than nb0, a≠b≠c, and i≠j≠k.

4. The apparatus as claimed in claim 2, wherein a set Scj1 constituted by non-minus-one elements in a c^{th} column of the basic parity check matrix Hbⱼ₁, among all the basic parity check matrices in the basic parity check matrix set except the Hbⱼ₀, from top to bottom is a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, MaxW is a positive integer, and c is an integer which is greater than or equal to 0 and is smaller than nb0.

5. The apparatus as claimed in claim 4, wherein a top-to-bottom sequence of all elements in the set Scj1 is identical to a top-to-bottom sequence of these elements in the set Scj0.

6. The apparatus as claimed in claim 2, wherein each basic parity check matrix Hbi in the basic parity check matrix set is equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

7. The apparatus as claimed in claim 6, wherein
the number of minus-one elements on different rows of the system bit part matrix of each basic parity check matrix in the basic parity check matrix set is equal or has a difference smaller than or equal to 2;
or
more than two or three continuous minus-one elements do not exist on each column of the system bit part matrix of each basic parity check matrix in the basic parity check matrix set;
or
more than two or three continuous minus-one elements do not exist on each row of the system bit part matrix in the basic parity check matrix set.

8. (canceled)

9. (canceled)

10. (canceled)

11. The apparatus as claimed in claim 1, wherein the condition that the short loops-4 in the Hbⱼ₁ are the same as the short loops-4 in the Hbⱼ₀ comprises that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner.

12. The apparatus as claimed in claim 1, wherein
any four elements [h_{ac}, h_{bc}, h_{bd}, h_{ad}] which are able to constitute a loop-4 in each basic parity check matrix of the basic parity check matrix set satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d;
or
the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 is minimum, where % is a modulo operator, zf is an expansion factor, a, b, c, i, j and k are any integers which are greater than or equal to 0 and are smaller than nb0, a≠b≠c and i≠j≠k;
or
a basic parity check matrix of which the number of matrix rows, j, is smaller than a maximum column weight MaxW in the basic parity check matrix set is equal to a matrix constituted by last j rows of the Hbⱼ₀, where the Hbⱼ₀ is a basic parity check matrix of which the number of matrix rows is equal to the maximum column weight MaxW, and MaxW and j are positive integers;
or
one or more elements among any four elements [hₐᵢ, h_{bi}, h_{bj}, hₐⱼ] constituting a loop-4 in all basic parity check matrices of the basic parity check matrix set belong to elements of which column weights are 2, and satisfy an inequality (hₐᵢ−h_{bi}+h_{bj}−hₐⱼ)% zf≠0; and one or more elements among any six elements └hₐᵢ, h_{bi}, h_{bj}, h_{cj}, h_{ck}, hₐₖ┘ constituting a short loop-6 in all basic parity check matrices of the basic parity check matrix set belong to elements of which column weights are 2, and satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c and i≠k.

13. (canceled)

14. (canceled)

15. (canceled)

16. (canceled)

17. The apparatus as claimed in claim 1, wherein the one or more processors encode the information bits to be encoded or decode the data to be decoded by means of the following modes: determining a block of the information bits to be encoded or a block of the data to be decoded, selecting a basic parity check matrix from the basic parity check matrix set according to the block of the information bits to be encoded or the block of the data to be decoded, and encoding the block of the information bits to be encoded or decoding the block of the data to be decoded based on the selected basic parity check matrix.

18. A method for processing information, comprising:
acquiring information bits to be encoded or data to be decoded; and
encoding the information bits to be encoded or decoding the data to be decoded using a pre-set basic parity check matrix set Hb, wherein at least 50 percent of short loops-4 in a basic parity check matrix Hbⱼ₁ among all basic parity check matrices in the basic parity check matrix set Hb except Hbⱼ₀ are the same as short loops-4 in the Hbⱼ₀, where j0 is a fixed positive integer between 0 and L−1, L is the number of basic parity check matrices contained in the basic parity check matrix set, and j1=0, 1, . . . , j0−1, j0+1, . . . , L−1.

19. The method as claimed in claim 18, wherein a dimension of each basic parity check matrix in the basic parity check matrix set is Mb×Nb, the number of columns Nb is a fixed value nb0, the number of rows Mb is mbi, and each mbi corresponds to one code rate ri, where ri is a real number greater than 0, i=0, 1, 2, . . . , L−1, mbi is an integer greater than 0, and nb0 is an integer greater than 0.

20. The method as claimed in claim 19, wherein
each of the short loops-4 is constituted by four non-minus-one elements [h_{ac}, h_{bc}, h_{bd}, h_{ad}] obtained by intersecting a c^{th} column and a d^{th} column with an a^{th} row and a b^{th} row in the basic parity check matrix, where a, b, c and d are any integers which are greater than or equal to 0 and are smaller than nb0, c<d, and a<b;
or,
the value of nb0 comprises: 8, 16, 24, 32, 40 or 48;
or
the value of ri is [½, ⅝, ¾, 13/16], i=0, 1, 2, 3, any four elements [hₐᵢ, h_{bi}, h_{bj}, hₐⱼ] constituting a loop-4 in a basic parity check matrix Hb0 of which a corresponding code rate r0=1/2 all satisfy an inequality (hₐᵢ−h_{bi}+h_{bj}−hₐⱼ)% zf≠0; and any six elements └hₐᵢ, h_{bi}, h_{bj}, h_{cj}, h_{ck}, hₐₖ┘ constituting a short loop-6 in the basic parity check matrix Hb0 all satisfy an inequality (hₐᵢ−h_{bi}+h_{bj}+h_{ck}−hₐₖ)% zf≠0, where % is a modulo operator, zf is an expansion factor, a, b, c, i, j and k are any integers which are greater than or equal to 0 and are smaller than nb0 a≠b≠c, and i≠j≠k.

21. The method as claimed in claim 19, wherein a set Scj1 constituted by non-minus-one elements in a c^{th} column in the basic parity check matrix Hbⱼ₁, among all the basic parity check matrices in the basic parity check matrix set except the Hbⱼ₀, from top to bottom is a subset of a set Scj0 constituted by non-minus-one elements in a c^{th} column of the Hbⱼ₀ from top to bottom, where the Hbⱼ₀ is a basic parity check matrix of which the number of matrix rows is equal to a maximum column weight MaxW, the maximum column weight MaxW refers to a column weight of a column with maximum weight among all columns of all basic parity check matrices in the basic parity check matrix set, MaxW is a positive integer, and c is an integer which is greater than or equal to 0 and is smaller than nb0.

22. The method as claimed in claim 21, wherein a top-to-bottom sequence of all elements in the set Scj1 is identical to a top-to-bottom sequence of these elements in the set Scj0.

23. The method as claimed in claim 19, wherein each basic parity check matrix Hbi in the basic parity check matrix set is equal to [Abi Bbi], where a matrix Abi is a system bit part matrix with a dimension of Mb×(Nb−Mb), a matrix Bbi is a check bit part matrix with a dimension of Mb×Mb, the number of rows of the matrix Abi is equal to the number of rows of the matrix Bbi, row weights of the matrices Abi and Bbi are greater than or equal to 1, and the matrix Bbi is a strictly lower triangular structure matrix or a double diagonal structure matrix.

24. The method as claimed in claim 23, wherein
the number of minus-one elements on different rows of the system bit part matrix of each basic parity check matrix in the basic parity check matrix set is equal or has a difference smaller than or equal to 2;
or
more than two or three continuous minus-one elements do not exist on each column of the system bit part matrix of each basic parity check matrix in the basic parity check matrix set;
or
more than two or three continuous minus-one elements do not exist on each row of the system bit part matrix in the basic parity check matrix set.

25. (canceled)

26. (canceled)

27. (canceled)

28. The method as claimed in claim 18, wherein the condition that the short loops-4 in the Hbⱼ₁ are the same as the short loops-4 in the Hbⱼ₀ comprises that: values of all corresponding elements of the short loops-4 in the Hbⱼ₁ and the short loops-4 in the Hbⱼ₀ are equal, two elements of each short loop-4 on a row of the Hbⱼ₁ are equal to two elements of each short loop-4 on a row of the Hbⱼ₀ in a one-to-one correspondence manner, and two elements of each short loop-4 on a column of the Hbⱼ₁ are equal to two elements of each short loop-4 on a column of the Hbⱼ₀ in a one-to-one correspondence manner.

29. The method as claimed in claim 18, wherein
any four elements [h_{ac}, h_{bc}, h_{bd}, h_{ad}] which are able to constitute a loop-4 in each basic parity check matrix of the basic parity check matrix set satisfy an inequality (h_{ac}−h_{bc}+h_{bd}−h_{ad})% zf≠0, where % is a modulo operator, zf is an expansion factor, a, b, c and d are any integers which are greater than or equal to 0 and are smaller than nb0, a≠b, and c≠d;
or
the number of any six elements └hₐᵢ, h_{bi}, h_{bj}, h_{cj}, h_{ck}, hₐₖ┘ which are able to constitute a loop-6 in all basic parity check matrices of the basic parity check matrix set and satisfy an inequality (hₐᵢ−h_{bi}+h_{bj}−h_{cj}+h_{ck}−hₐₖ)% zf==0 is minimum, where % is a modulo operator, zf is an expansion factor, a, b, c, i, j and k are any integers which are greater than or equal to 0 and are smaller than nb0, a≠b≠c and i≠j≠k;
or
a basic parity check matrix of which the number of matrix rows, j, is smaller than a maximum column weight MaxW in the basic parity check matrix set is equal to a matrix constituted by last j rows of the Hbⱼ₀, where the Hbⱼ₀ is a basic parity check matrix of which the number of matrix rows is equal to the maximum column weight MaxW and MaxW and j are positive integers;
or
one or more elements among any four elements [hₐᵢ, h_{bi}, h_{bj}, hₐⱼ] constituting a loop-4 in all basic parity check matrices of the basic parity check matrix set belong to elements of which column weights are 2, and satisfy an inequality (hₐᵢ−h_{bi}+h_{bj}−hₐⱼ)% zf≠0; and one or more elements among any six elements └hₐᵢ, h_{bi}, h_{bj}, h_{cj}, h_{ck}, hₐₖ┘ constituting a short loop-6 in all basic parity check matrices of the basic parity check matrix set belong to elements of which column weights are 2, and satisfy an inequality (hₐᵢ−h_{bi}+h_{bj}−h_{cj}+h_{ck}−hₐₖ)% zf≠0, where % is a modulo operator, zf is an expansion factor, a, b, c, i, j and k are any integers which are greater than or equal to 0 and are smaller than nb0, a≠b≠c and i≠j≠k.

30. (canceled)

31. (canceled)

32. (canceled)

33. (canceled)

34. The method as claimed in claim 18, wherein encoding the information bits to be encoded or decoding the data to be decoded using the pre-set basic parity check matrix set Hb comprises: determining a block of the information bits to be encoded or a block of the data to be decoded, selecting a basic parity check matrix from the basic parity check matrix set according to the block of the information bits to be encoded or the block of the data to be decoded, and encoding the block of the information bits to be encoded or decoding the block of the data to be decoded based on the selected basic parity check matrix.
